(19) United States
(12) Patent Application Publication
(10) Pub. No.: US 2026/0110972 A1
(43) Pub. Date: Apr. 23, 2026

(54) DEVELOPING PROCESSES FOR CHEMICALLY AMPLIFIED RESISTS

(71) Applicant: Applied Materials, Inc., Santa Clara, CA (US)

(72) Inventors: LIKUN WANG, Cupertino, CA (US); NASRIN KAZEM, Santa Clara, CA (US); RUDY WOJTECKI, East Garrison, CA (US); LARRY GAO, Fremont, CA (US)

(21) Appl. No.: 19/333,184

(22) Filed: Sep. 18, 2025

Related U.S. Application Data
(60) Provisional application No. 63/708,709, filed on Oct. 17, 2024.

(51) Int. Cl. G03F 7/38; G03F 7/09; G03F 7/40

(52) U.S. Cl. CPC G03F 7/38; G03F 7/094; G03F 7/40

(57) ABSTRACT

Embodiments described herein relate to a method of developing a chemically amplified resist (CAR) that is provided over an underlayer that includes carbon and fluorine, where the CAR has been selectively exposed with a lithography process to form a latent image. In an embodiment, the method includes incorporating a metal into the CAR after the lithography process, and developing the CAR to form an opening in the CAR.

### CROSS-REFERENCE TO RELATED APPLICATIONS

This application claims the benefit of U.S. Provisional Application No. 63/708,709, filed on Oct. 17, 2024, the entire contents of which are hereby incorporated by reference herein.

### BACKGROUND

### 1) FIELD

Embodiments relate to the field of semiconductor manufacturing and, in particular, dry development processes for a chemically amplified resist (CAR).

### 2) DESCRIPTION OF RELATED ART

Extreme ultraviolet (EUV) photoresists allow for the continued scaling to smaller features that are patterned on a semiconductor substrate. In an EUV lithography process, EUV radiation is selectively applied to regions of the photoresist layer in order to generate a solubility switch that enables the formation of a latent image within the photoresist layer. The latent image corresponds to the portions of the photoresist layer that have undergone the solubility switch as a result of a chemical reaction that is induced by the EUV exposure. After the latent image is produced within the photoresist layer, a developing process may be used in order to generate a pattern in the photoresist layer.

Typically, EUV compatible resists suffer from poor sensitivity. That is, a large dose is needed in order to provide the necessary solubility switch in order to provide adequate pattern formation (e.g., with suitable line edge roughness (LER), line width roughness (LWR), critical dimension (CD) uniformity, and/or the like). The larger dose increases the exposure time, which may be a bottleneck in the EUV lithography process. As such, throughput may be limited in EUV lithography processes.

One solution to reduce the necessary dose is to incorporate an underlayer below the resist layer. The underlayer may also react to the EUV exposure in order to diffuse species into the overlying resist layer. The additional species diffused into the resist layer may participate in the chemical reactions (e.g., deprotection reactions) in order to allow for lower overall EUV doses. However, the underlayer may also provide generate issues during the patterning process. For example, adhesion between the resist layer and the underlayer may not be high enough to prevent pattern collapse or other pattern damage. Additionally, etch selectivity between the resist layer and the underlayer may not be high. As such, a thicker resist layer may be necessary. Increasing the thickness of the resist layer may not be desirable since this may negatively impact one or more parameters of the pattern.

### SUMMARY

Embodiments described herein relate to a method of developing a chemically amplified resist (CAR) that is provided over an underlayer that includes carbon and fluorine, where the CAR has been selectively exposed with a lithography process to form a latent image. In an embodiment, the method includes incorporating a metal into the CAR after the lithography process, and developing the CAR to form an opening in the CAR.

Embodiments described herein relate to a method for developing a selectively exposed chemically amplified resist (CAR) that is provided over a underlayer including carbon and fluorine. In an embodiment, the method includes developing the CAR to form an opening in the CAR, and forming a protection layer over the CAR. In an embodiment, a first etch selectivity between the protection layer and the underlayer is higher than a second etch selectivity between the CAR and the underlayer.

Embodiments described herein relate to a method of developing a chemically amplified resist (CAR) that is provided over an underlayer including carbon and fluorine, where the CAR has been selectively exposed with a lithography process to form a latent image. In an embodiment, the method includes incorporating a metal into the CAR, and developing the CAR with a dry develop process to form an opening in the CAR. In an embodiment, the method comprises depositing a protection layer over the CAR after the opening is formed in the CAR.

Embodiments described herein relate to a method for developing a selectively exposed chemically amplified resist (CAR) that is provided over a underlayer including carbon and fluorine. In an embodiment the method includes developing the CAR with a dry develop process to form an opening in the CAR.

### DESCRIPTION OF THE DRAWINGS

FIG. 1A-1F are illustrations depicting a process for patterning a chemically amplified resist (CAR) with an underlayer using a dry develop process, in accordance with an embodiment.

FIG. 2 is a flow diagram depicting a process for patterning a CAR with an underlayer using a dry develop process, in accordance with an embodiment.

FIG. 3A-3D are illustrations depicting a process for patterning a CAR with an underlayer and a selectively deposited protection layer over the CAR with a dry develop process, in accordance with an embodiment.

FIG. 4 is a flow diagram depicting a process for patterning a CAR with an underlayer and a selectively deposited protection layer over the CAR with a dry develop process, in accordance with an embodiment.

FIG. 5 illustrates a block diagram of an exemplary computer system that may be used in conjunction with a processing tool, in accordance with an embodiment.

### DETAILED DESCRIPTION

Embodiments described herein include dry development processes for a chemically amplified resist (CAR). In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, EUV photoresist materials may suffer from poor sensitivity, and high EUV doses are needed in order to provide a desired patterning result. One solution to improve the sensitivity of EUV photoresists may include the addition of an underlayer below the photoresist layer. In the case of a chemically amplified resist (CAR), the underlayer may contribute to the deprotection reaction within the CAR in order to reduce the dose necessary to provide a desired solubility switch. As such, a reduction in the dose may be enabled.

However, the underlayer may also provide additional issues to the patterning. For example, adhesion between the resist layer and the underlayer may not be high enough to prevent pattern collapse or other pattern damage. Additionally, etch selectivity between the resist layer and the underlayer may not be high. As such, a thicker resist layer may be necessary. Increasing the thickness of the resist layer may not be desirable since this may negatively impact one or more parameters of the pattern.

Accordingly, embodiments disclosed herein include a CAR and underlayer combination that is patterned with a dry develop process. The use of a dry develop process maximizes the adhesion strength between the underlayer and the CAR since a liquid etchant chemistry is not present. This allows for the underlayer to be maintained within the patterning stack in order to provide the improvements to dose reduction.

In some embodiments, the underlayer may comprise carbon and fluorine. For example, the underlayer may comprise an organic polymer material that is fluorine doped. As such, an etch selectivity between the CAR and the underlayer may not be as high as desired. Accordingly, a thick CAR layer may be used in order to prevent the CAR from being completely removed during the transfer of the pattern in the CAR into the underlayer. A relatively thick CAR may result in poor metal penetration during a treatment process (e.g., a sequential infiltration synthesis (SIS) process). Additionally, larger thicknesses may create higher aspect ratios for the pattern formed in the CAR, which can be detrimental to patterning performance.

Accordingly, embodiments disclosed herein may include the deposition of a protective layer over the CAR after the CAR is developed. The protective layer may be selectively formed over the top surface of the CAR with a dry deposition process in some embodiments. In an embodiment, the protective layer may have a higher etch selectivity with respect to the underlayer than an etch selectivity between the CAR and the underlayer. In some embodiments, the protective layer may comprise silicon and oxygen (e.g., SiO₂). Since the CAR is protected while the pattern is transferred into the underlayer, the thickness of the CAR may be reduced. This allows for improved metal precursor penetration into the CAR.

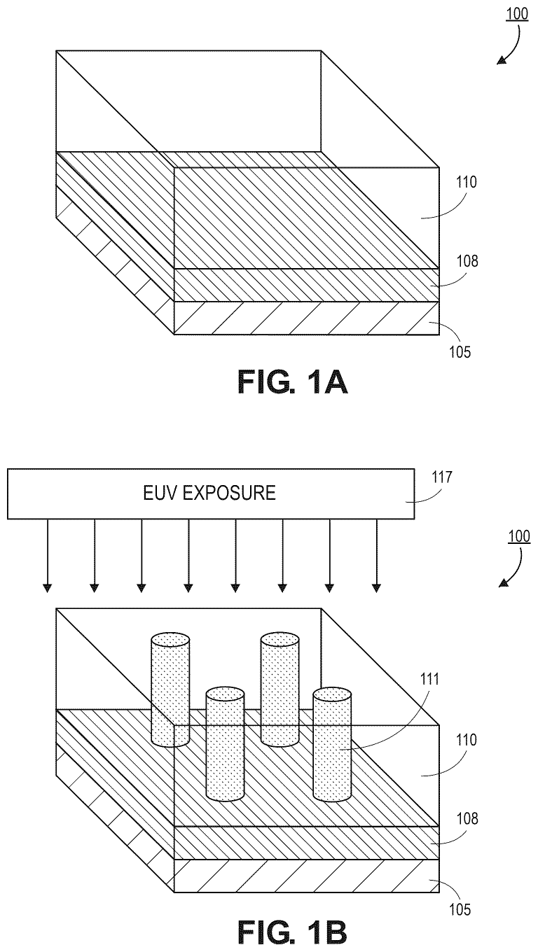

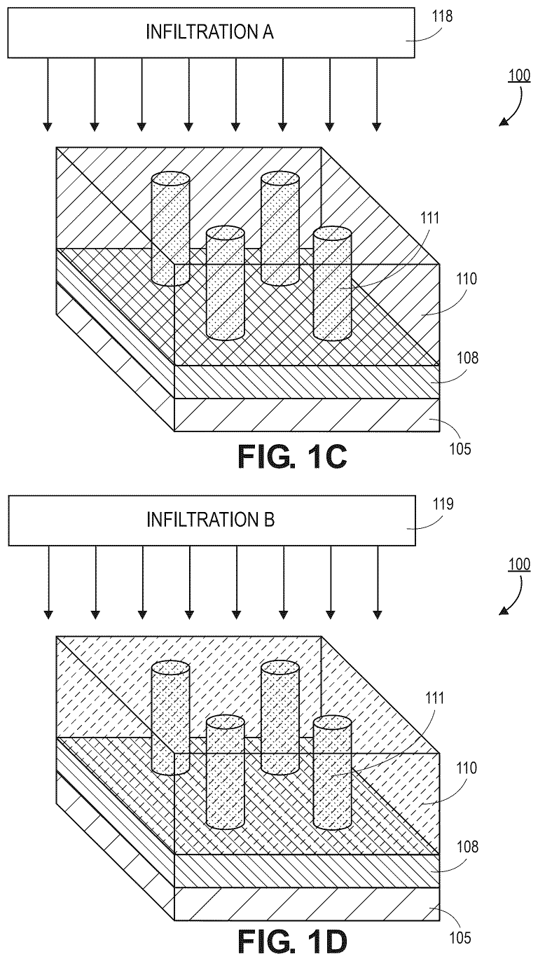

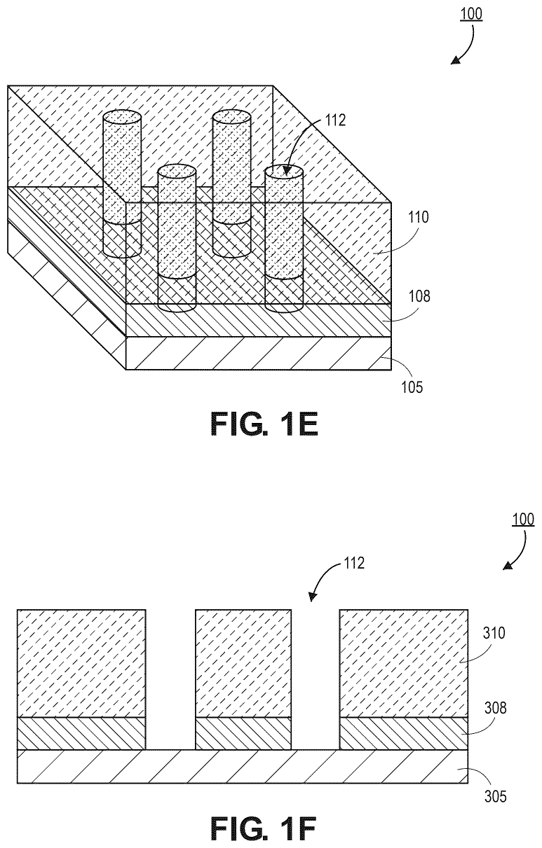

Referring now to FIG. 1A-1F, a series of illustrations depicting a process for patterning a portion of a device 100 with a resist layer 110 is shown, in accordance with an embodiment.

Referring now to FIG. 1A, a perspective view illustration of a portion of the device 100 is shown, in accordance with an embodiment. In an embodiment, the device 100 may comprise a substrate 105. The substrate 105 may comprise a semiconductor substrate, such as a silicon wafer or the like. In other embodiments, the substrate 105 may comprise one or more of a dielectric layer (e.g., an oxide layer, a nitride layer, or the like), a metallic layer, and/or the like over a semiconductor substrate. In an embodiment, the substrate 105 may also comprise a patterning stack (not shown). A patterning stack may comprise one or more layers suitable for transferring a pattern formed into the resist layer 110 into the underlying substrate 105. For example, the patterning stack may comprise one or more of a silicon hardmask layer, a carbon hardmask layer, an antireflective coating, and/or the like.

In an embodiment, an underlayer 108 is provided over the substrate 105. For example, the underlayer 108 may be provided between the resist layer 110 and the substrate 105. In some embodiments, the underlayer 108 may be considered as part of the patterning stack, despite being shown as a distinct layer. In an embodiment, the underlayer 108 may comprise a chemical structure that is reactive to the deep ultraviolet (DUV) and/or extreme ultraviolet (EUV) radiation in order to generate species that can diffuse into the overlying resist layer 110 in order to help drive the chemical reaction within the resist layer 110 that leads to a solubility switch in the resist layer 110. In some embodiments, the underlayer 108 may comprise carbon and fluorine. For example, the underlayer 108 may be an organic polymer, such as a polymer comprising carbon. In some embodiments, the underlayer 108 may be doped with fluorine. For example, the underlayer 108 may comprise between 0 atomic percent fluorine and approximately 70.0 atomic percent fluorine in some embodiments.

In an embodiment, the resist layer 110 may include any suitable photoresist material that is compatible with DUV and/or EUV lithography. In a particular embodiment, the resist layer 110 is a CAR material or an organometallic oxide material. For example, the resist layer 110 may comprise a polymer with photoacid generators (PAGs). Upon exposure to DUV and/or EUV radiation, the PAGs produce acids that diffuse and initiate deprotection reactions that drive a solubility switch in the resist layer 110. As noted above, the DUV and/or EUV exposure of the underlayer may result in the diffusion of additional species into the resist layer 110 in order to participate in the deprotection reactions.

Referring now to FIG. 1B, a perspective view illustration of the portion of the device 100 after an exposure process is shown, in accordance with an embodiment. In an embodiment, a latent image 111 is formed into the resist layer 110 by exposure 117 to radiation of a particular wavelength or wavelengths. For example, DUV radiation, EUV radiation, or the like may be used to initiate a solubility switch within the resist layer 110. The exposure may be made through a mask, a reticle, or the like (not shown). The resist layer 110 may also be exposed through a laser exposure, electron beam exposure, or the like.

In an embodiment, the latent image 111 represents a portion of the resist layer 110 that has undergone a deprotection reaction. That is, the latent image 111 has undergone a solubility switch that allows for the latent image to be selectively removed with a developing process, as will be described in greater detail herein. In an embodiment, the device 100 may be baked after the exposure 117 in order to drive the deprotection reaction.

In an embodiment, the latent image 111 is shown as having a pattern that includes a plurality of high aspect ratio columns. Such a pattern may suitable for forming holes in the underlying substrate 105 (e.g., to form vias or the like). Though, embodiments may include a latent image 111 with any suitable pattern. For example, the latent image 111 may have a pattern that includes lines. Such a pattern may be suitable for forming traces in the underlying substrate 105. Though, embodiments may also include a latent image 111 that includes a pattern with high aspect ratio columns and lines.

Referring now to FIGS. 1C and 1D, a series of perspective view illustrations that depict a treatment process that is applied to the exposed resist layer 110 is shown, in accordance with an embodiment. In an embodiment, the treatment process may include the infiltration of the resist layer 110 with a metal. For example, the metal may include aluminum. More specifically, the treatment process may include an SIS process.

For example, in FIG. 1C, a first infiltration 118 is used to diffuse a first precursor into the resist layer 110. In an embodiment, the first precursor may comprise a metal. For example, the first precursor may comprise a metal-organic precursor, such as trimethylaluminum (TMA). The first precursor may be applied to the resist layer 110 in a chamber with a relatively high pressure in order to drive the first precursor into the resist layer 110. Accordingly, the metal of the first precursor may be incorporated into the resist layer 110.

Referring now to FIG. 1D, a second infiltration 119 is used to diffuse a second precursor into the resist layer 110. In an embodiment, the second precursor may comprise H₂O or any other suitable co-reactant. The resist layer 110 may be exposed to the second precursor after a purge is implemented after the first precursor is flown into the chamber. In an embodiment, the first infiltration 118 and the second infiltration 119 may be cycled any number of times (e.g., one or more times, ten or more times, fifty or more times, or one hundred or more times).

The incorporation of metal into the resist layer 110 may provide for better development in subsequent processing operations. For example, the incorporation of metal into the resist layer 110 may improve etch resistance, LER, LWR, mechanical stability of the pattern (e.g., to prevent pattern collapse), or the like.

Referring now to FIG. 1E, a perspective view illustration of the device 100 after a developing process is shown, in accordance with an embodiment. In an embodiment, the developing process is a dry develop process. The use of a dry process reduces the probability of pattern collapse and improves LER and/or LWR compared to wet etching processes. As noted herein, the use of a wet etching chemistry negatively impacts adhesion between the underlayer 108 and the resist layer 110. Further, wet etching processes will generate capillary forces from the wet etchant. Spinning the substrate during drying may also induce forces on the resist layer 110. These additional forces may bend and/or tip over lines in the resist layer, and/or negatively impact the LER and/or LWR.

In one embodiment, the dry develop process may include a reactive ion etching (RIE) process. Though, any suitable dry develop process may be used. As used herein, a “dry develop” process may refer to a subtractive process that removes a portion of the resist layer 110 (e.g., the exposed region of the resist layer 110 forming the latent image 111) through a reaction without the use of a liquid chemistry. In some embodiments, a developing process may also refer to etching process.

As shown in FIG. 1E, the develop process may result in the formation of openings 112 in the resist layer 110. For example, in FIG. 1E the openings 112 are holes. Though, in the case of the latent image comprising lines, the developing process may form trenches through the resist layer 110. In the illustrated embodiment, the developing process may also etch through the underlayer 108. In some embodiments, a single dry developing process may be used to form the openings 112 through the resist layer 110 and the underlayer 108. In other embodiments, a first dry developing processes may be used to for the openings 112 and the pattern of the openings 112 may be transferred into the underlayer 108 with a second dry developing process.

Referring now to FIG. 1F, a cross-sectional illustration of the device 100 is shown, in accordance with an embodiment. In an embodiment, the cross-sectional illustration of FIG. 1F more clearly illustrates the openings 112 through the resist layer 110 and the underlayer 108. As shown, the openings 112 may be relatively high aspect ratio features. For example, a height: width aspect ratio of the openings 112 may be 2:1 or greater, 5:1 or greater, 10:1 or greater, or 20:1 or greater.

In an embodiment, after the openings 112 are formed through the resist layer 110 and the underlayer 108, the pattern of the openings 112 may be transferred into the underlying substrate 105 (or any other intervening layers, such as a patterning stack or the like).

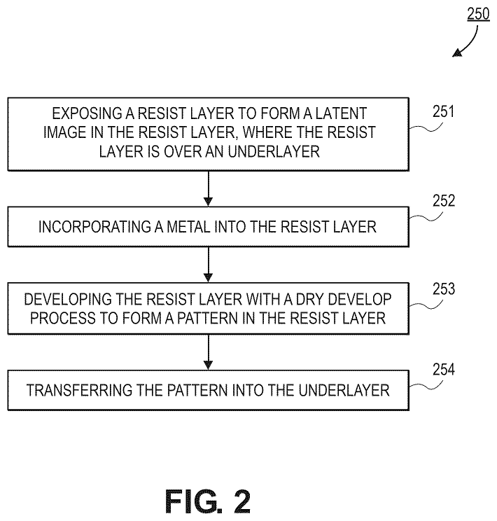

Referring now to FIG. 2, a flow diagram that depicts a process 250 for forming a pattern in a resist layer that is over an underlayer is shown, in accordance with an embodiment. In an embodiment, the process 250 may begin with operation 251, which comprises exposing a resist layer to form a latent image in the resist layer, where the resist layer is over an underlayer. In an embodiment, the resist layer may comprise a CAR or an organometallic oxide resist material, such as any of those described in greater detail herein. In an embodiment, the resist layer is exposed with DUV and/or EUV radiation. The latent image may have a pattern that comprises one or more pillars and/or one or more lines.

In an embodiment, the process 250 may continue with operation 252, which comprises incorporating a metal into the resist layer. In an embodiment, the metal may be incorporated into the resist layer with an SIS process or the like. In some embodiments, the metal may comprise aluminum. For example, an SIS process may include one or more cycles of infiltration with a first precursor that is a metal-organic precursor, such as TMA, and a second precursor, such as H₂O.

In an embodiment, the process 250 may continue with operation 253, which comprises developing the resist layer with a dry develop process to form a pattern in the resist layer. In an embodiment, the dry develop process may include any chemistry and/or process that reacts with the latent image portion of the resist layer in order to form openings through the resist layer. In one embodiment, the dry develop process may include a RIE process or the like.

In an embodiment, the process 250 may continue with operation 254, which comprises transferring the pattern of the openings into the underlayer. The pattern of the openings may be formed in the underlayer through a dry etching process. In some embodiments, the dry etching process used to pattern the underlayer may be the same process used to develop the resist layer. Though, in other embodiments, the resist layer and the underlayer may be patterned with different dry developing and/or etching processes.

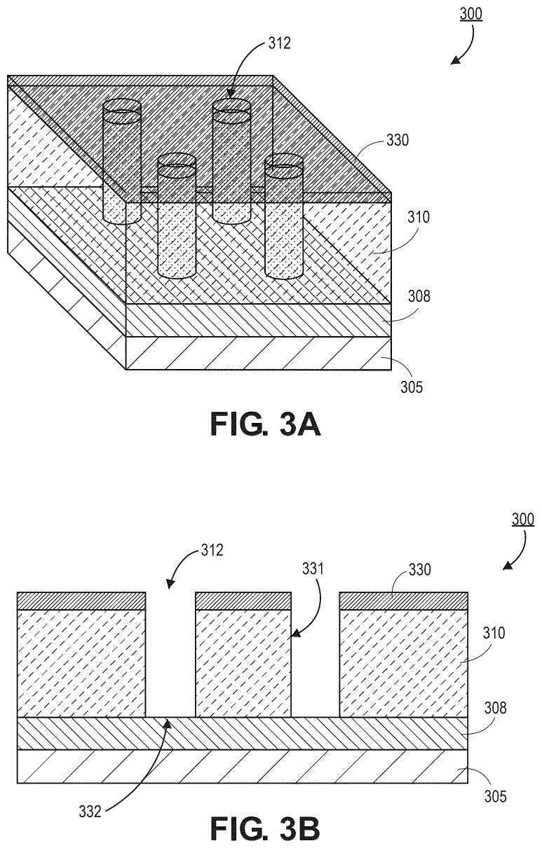

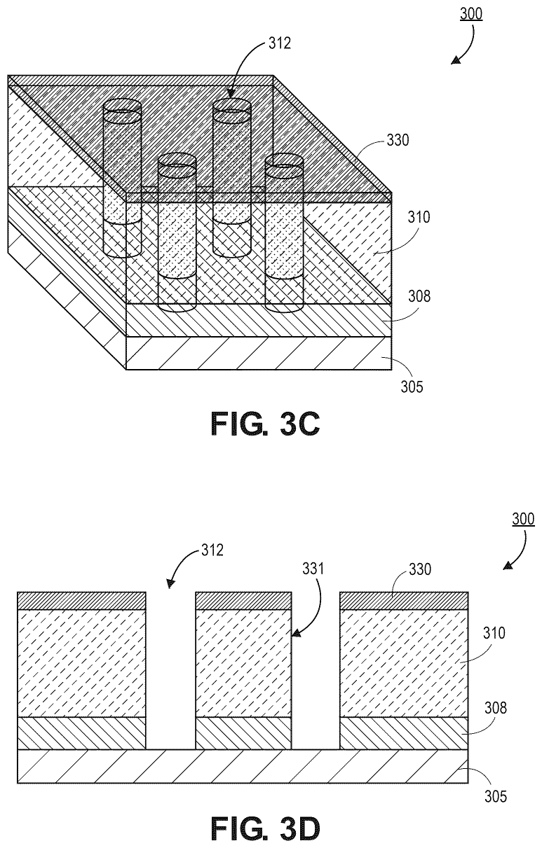

Referring now to FIG. 3A-3D, a series of illustrations depicting a process for forming a pattern in a resist layer 310 of a device 300 is shown, in accordance with an additional embodiment. The embodiments described with respect to FIG. 3A-3D differ from FIG. 1A-1F in that a protective layer 330 is also provided over the developed resist layer. The protective layer 330 may improve etch selectivity of the underlayer 308. Accordingly, a thickness of the resist layer 310 may be reduced. This provides several benefits, such as improved metal infiltration efficiency, improved pattern quality, and/or the like, as described in greater detail herein.

Referring now to FIG. 3A, a perspective view illustration of a portion of a device 300 is shown, in accordance with an embodiment. In an embodiment, the device 300 may be similar to the device 100 described in greater detail above. For example, the device 100 may comprise a substrate 305 (e.g., a semiconductor substrate or the like). A resist layer 310 and an underlayer 308 may be provided over the substrate 305. In an embodiment, the resist layer 310 may comprise a CAR or an organometallic oxide resist material. The underlayer 308 may comprise an organic polymer. For example, the underlayer 308 may comprise carbon, and the underlayer 308 may be fluorine doped in some embodiments.

At the stage of manufacture illustrated in FIG. 3A, the resist layer 310 has been exposed, treated to incorporate a metal in the resist layer 310, and developed with a dry develop process. For example, the resist layer 310 may be in a state similar to the state of the resist layer 110 shown in FIG. 1E. That is, similar processing operations described in FIG. 1A-1D may be used to form a resist layer 310 similar to the one shown in FIG. 3A. For example, a DUV and/or EUV lithography process may form a latent image in the resist layer, and a metal infiltration process (e.g., an SIS process comprising one or more cycles of a TMA precursor and an H₂O precursor) may be used to treat the resist layer 310. In an embodiment, the resist layer 310 may be developed with a dry developing process, such as a RIE process or the like. The openings 312 formed through the resist layer 310 are shown as holes. Though, in other embodiments, trenches used to form a line-space pattern may also be formed.

In an embodiment, FIG. 3A differs from FIG. 1E in that a protective layer 330 is formed over the top surface of the resist layer 310. The protective layer 330 may comprise a material that is more resistant to an etching chemistry used to pattern the underlayer 308 compared to the resist layer 310. For example, an etch selectively of the underlayer 308 to the protective layer 330 is higher than an etch selectivity of the underlayer 308 to the resist layer 310.

In a particular embodiment, the protective layer 330 may comprise silicon and oxygen (e.g., SiO₂ or the like). The protective layer 330 may be selectively deposited over the surface of the developed resist layer 310 with a dry deposition process. In an embodiment, the selectivity may be provided, at least in part, by the geometry of the openings 312. That is, the deposition process may deposit preferentially over the top surface of the resist layer 310 instead of the sidewall surfaces 331 of the openings 312 and/or the exposed top surface 332 of the underlayer 308 (as shown in the cross-sectional illustration of FIG. 3B) due to the aspect ratio of the openings 312. While there is no protective layer 330 shown over the sidewall surfaces 331 or the top surface 332 of the underlayer 308, in some embodiments some amount of the protective layer 330 may deposit on the sidewall surfaces 331 and/or the top surface 332 of the underlayer. Though, a thickness of such portions of the protective layer 330 may be less than a thickness of the protective layer 330 over the top surface of the resist layer 310.

In an embodiment, the dry deposition process used to deposit the protective layer 330 may comprise flowing processing gasses comprising silicon and oxygen into a chamber. For example, processing gasses such as SiCl₄ and O₂ may be used to deposit a SiO₂ protective layer 330 over the resist layer 310. In an embodiment, a thickness of a portion of the protective layer 330 over the top surface of the resist layer 310 may be up to approximately 5 nm, up to approximately 10 nm, or up to approximately 20 nm. Though, thicker protection layers 330 may also be used in some embodiments.

In an embodiment, the presence of the protection layer 330 allows for the thickness of the resist layer 310 to be reduced, since the risk of completely removing the resist layer 310 during the transfer of the pattern of the openings 312 into the underlayer 308 is minimized. Reducing the thickness of the resist layer 310 allows for improved infiltration, reduced dosages, reduced aspect ratios, and/or improved patterning outcomes.

Referring now to FIGS. 3C and 3D, a perspective view illustration and a corresponding cross-sectional illustration of the portion of the device 300 after the pattern of the openings 312 is transferred into the underlayer 308 is shown, in accordance with an embodiment. In an embodiment, the underlayer 308 may be etched with a dry etching process. Due to the presence of the protective layer 330, the etching process does not have to be as carefully controlled since the resist layer 310 is protected. After the underlayer 308 is patterned, the pattern of the openings 312 may be transferred into any underlying layers, such as the substrate 305 or the like.

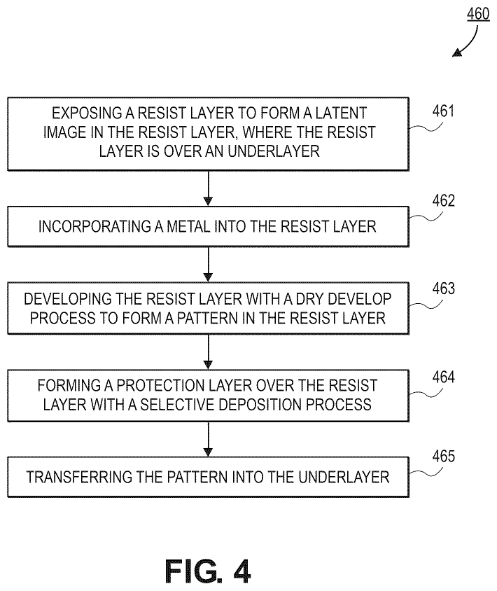

Referring now to FIG. 4, a flow diagram that depicts a process 460 for forming a pattern in a resist layer that is over an underlayer is shown, in accordance with an embodiment. In an embodiment, the process 460 may begin with operation 461, which comprises exposing a resist layer to form a latent image in the resist layer, where the resist layer is over an underlayer. In an embodiment, the resist layer may comprise a CAR or an organometallic oxide resist material, such as any of those described in greater detail herein. In an embodiment, the resist layer is exposed with DUV and/or EUV radiation. The latent image may have a pattern that comprises one or more pillars and/or one or more lines.

In an embodiment, the process 460 may continue with operation 462, which comprises incorporating a metal into the resist layer. In an embodiment, the metal may be incorporated into the resist layer with an SIS process or the like. In some embodiments, the metal may comprise aluminum. For example, an SIS process may include one or more cycles of infiltration with a first precursor that is a metal-organic precursor, such as TMA, and a second precursor, such as H₂O.

In an embodiment, the process 460 may continue with operation 463, which comprises developing the resist layer with a dry develop process to form a pattern in the resist layer. In an embodiment, the dry develop process may include any chemistry and/or process that reacts with the latent image portion of the resist layer in order to form openings through the resist layer. In one embodiment, the dry develop process may include a RIE process or the like.

In an embodiment, the process 460 may continue with operation 464, which comprises forming a protection layer over the resist layer with a selective deposition process. In an embodiment, the deposition process may be a dry deposition process, such as a chemical vapor deposition process or the like. In an embodiment, the protection layer may comprise an etch selectivity to the underlayer that is higher than an etch selectivity between the resist layer and the underlayer. For example, the protection layer may comprise silicon and oxygen (e.g., SiO₂). In an embodiment, processing gasses such comprising silicon and oxygen (e.g., SiCl₄ and O₂) may be flown into the chamber to deposit the protection layer on the resist layer. In an embodiment, a thickness of the protection layer may be up to approximately 5 nm, up to approximately 10 nm, or up to approximately 20 nm.

In an embodiment, the process 460 may continue with operation 465, which comprises transferring the pattern of the openings into the underlayer. The pattern of the openings may be formed in the underlayer through a dry etching process. After the openings are formed in the underlayer, the pattern may be transferred into any underlying layers (e.g., a patterning stack, a substrate, or the like).

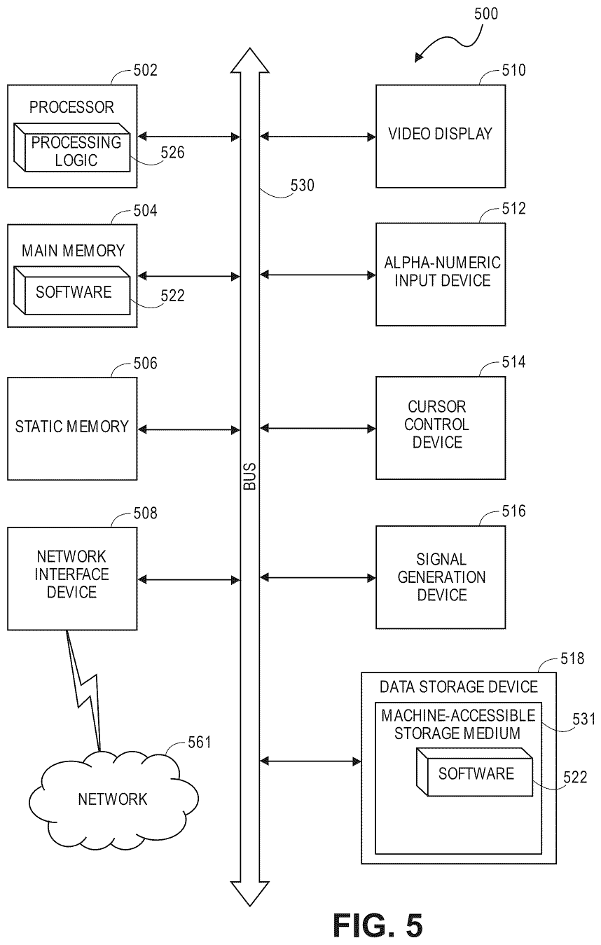

Referring now to FIG. 5, a block diagram of an exemplary computer system 500 of a processing tool is illustrated in accordance with an embodiment. In an embodiment, computer system 500 is coupled to and controls processing in the processing tool. Computer system 500 may be connected (e.g., networked) to other machines in a Local Area Network (LAN), an intranet, an extranet, or the Internet. Computer system 500 may operate in the capacity of a server or a client machine in a client-server network environment, or as a peer machine in a peer-to-peer (or distributed) network environment. Computer system 500 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 500, the term “machine” shall also be taken to include any collection of machines (e.g., computers) that individually or jointly execute a set (or multiple sets) of instructions to perform any one or more of the methodologies described herein.

Computer system 500 may include a computer program product, or software 522, having a non-transitory machine-readable medium having stored thereon instructions, which may be used to program computer system 500 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 500 includes a system processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

System processor 502 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 502 may also be one or more special-purpose processing devices such as an application specific integrated circuit (ASIC), a field programmable gate array (FPGA), a digital signal system processor (DSP), network system processor, or the like. System processor 502 is configured to execute the processing logic 526 for performing the operations described herein.

The computer system 500 may further include a system network interface device 508 for communicating with other devices or machines. The computer system 500 may also include a video display unit 510 (e.g., a liquid crystal display (LCD), a light emitting diode display (LED), or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium 531 (or more specifically a computer-readable storage medium) on which is stored one or more sets of instructions (e.g., software 522) embodying any one or more of the methodologies or functions described herein. The software 522 may also reside, completely or at least partially, within the main memory 504 and/or within the system processor 502 during execution thereof by the computer system 500, the main memory 504 and the system processor 502 also constituting machine-readable storage media. The software 522 may further be transmitted or received over a network 561 via the system network interface device 508. In an embodiment, the network interface device 508 may operate using RF coupling, optical coupling, acoustic coupling, or inductive coupling.

While the machine-accessible storage medium 531 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method of developing a chemically amplified resist (CAR) that is provided over an underlayer that comprises carbon and fluorine, wherein the CAR has been selectively exposed with a lithography process to form a latent image, the method comprising:
incorporating a metal into the CAR after the lithography process; and
developing the CAR to form an opening in the CAR.

2. The method of claim 1, further comprising:
forming a protection layer over the CAR.

3. The method of claim 2, wherein the protection layer comprises silicon and oxygen.

4. The method of claim 2, wherein a portion of the protection layer above the CAR has a thickness up to 20 nm.

5. The method of claim 2, wherein the protection layer has a first thickness over a top surface of the CAR that is greater than a second thickness of the protection layer over a sidewall surface of the opening.

6. The method of claim 2, wherein the protection layer is deposited with a dry deposition process.

7. The method of claim 1, wherein the CAR is developed with a dry develop process or a wet develop process after the metal is incorporated into the CAR.

8. The method of claim 1, wherein incorporating the metal into the CAR comprises a sequential infiltration synthesis (SIS) process.

9. The method of claim 8 wherein the SIS process comprises exposing the CAR to trimethylaluminum (TMA) in a chamber, purging the chamber, and exposing the CAR to H₂O in the chamber.

10. The method of claim 8, wherein the SIS process is cycled a plurality of times.

11. The method of claim 1, further comprising:
transferring a pattern of the opening into the underlayer after developing the CAR.

12. A method for developing a selectively exposed chemically amplified resist (CAR) that is provided over a underlayer comprising carbon and fluorine, the method comprising:
developing the CAR to form an opening in the CAR; and
forming a protection layer over the CAR, wherein a first etch selectivity between the protection layer and the underlayer is higher than a second etch selectivity between the CAR and the underlayer.

13. The method of claim 12, further comprising:
incorporating a metal into the CAR through a sequential infiltration synthesis (SIS) process before developing the CAR.

14. The method of claim 12, wherein the protection layer comprises silicon and oxygen.

15. The method of claim 12, wherein the CAR is developed with a dry develop process.

16. The method of claim 12, further comprising:
transferring a pattern of the opening into the underlayer after forming the protection layer over the CAR.

17. A method of developing a chemically amplified resist (CAR) that is provided over an underlayer comprising carbon and fluorine, wherein the CAR has been selectively exposed with a lithography process to form a latent image, the method comprising:
incorporating a metal into the CAR;
developing the CAR with a dry develop process to form an opening in the CAR; and
depositing a protection layer over the CAR after the opening is formed in the CAR.

18. The method of claim 17, wherein incorporating the metal into the CAR comprises:
exposing the CAR to a first precursor that comprises the metal; and
exposing the CAR to a second precursor.

19. The method of claim 18, wherein the first precursor comprises trimethylaluminum (TMA), and wherein the second precursor comprises H₂O.

20. The method of claim 18, further comprising repeating exposing the CAR to the first precursor and exposing the CAR to the second precursor a plurality of times.
